(19) United States
(12) Patent Application Publication
(10) Pub. No.: US 2014/0340862 A1
(43) Pub. Date: Nov. 20, 2014

(54) ELECTRONIC DEVICE WITH SUPPORTING APPARATUS

(71) Applicants: HON HAI PRECISION INDUSTRY CO., LTD., New Taipei (TW); HONG FU JIN PRECISION INDUSTRY (WuHan) CO. LTD., Wuhan (CN)

(72) Inventors: CHUN-YONG XU, Wuhan (CN); HE-TAO HAN, Shenzhen (CN); LIU-SHA DENG, Shenzhen (CN); CHANG-SHENG ZHOU, Shenzhen (CN); GUANG-TIAN WAN, Wuhan (CN); YONG-GAO LIAO, Wuhan (CN); JUN-HUA TAN, Shenzhen (CN); SONG DENG, Shenzhen (CN); YI-SHENG LIN, New Taipei (TW); WEN-KANG LO, New Taipei (TW); YI-TING HSIEH, New Taipei (TW); GUANG-YAO LEE, New Taipei (TW)

(21) Appl. No.: 13/928,187

(22) Filed: Jun. 26, 2013

(30) Foreign Application Priority Data
May 20, 2013 (CN) 2013101866331

(51) Int. Cl. F16M 11/10; H05K 5/02

(52) U.S. Cl. CPC F16M 11/10; H05K 5/0226
USPC 361/807; 248/688

(57) ABSTRACT

An electronic device includes a main body, an installing assembly, a support, and a connecting assembly. The main body includes a shell and a display screen installed in the shell. The installing assembly is connected to a side of the shell opposite to the display screen. The connecting assembly is rotatably connected between the installing assembly and the support. The support includes a connecting pole and two opposite extending poles perpendicularly extending out from two opposite ends of the connecting pole. The connecting pole and the extending poles cooperatively bound a receiving space. The connecting assembly can be rotated to be received in the receiving space.

### BACKGROUND

1. Technical Field

The present disclosure relates to electronic devices, and more particularly, to an electronic device with a supporting apparatus.

2. Description of Related Art

An electronic device, such as a display device, often includes a display and a supporting apparatus supporting the display. The supporting apparatus is mounted to the display by screws. Thus, the display cannot be rotated relative to the supporting apparatus, which is inconvenient in use.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of an electronic device, wherein the electronic device includes an installing assembly, a support, and a connecting assembly.

FIG. 2 is similar to FIG. 1, but viewed from another perspective.

FIG. 3 is an enlarged view of the installing assembly of FIG. 1.

FIG. 4 is an enlarged view of the support and the connecting assembly of FIG. 2.

FIG. 5 is an assembled, isometric view of the electronic device of FIG. 2.

FIGS. 6-9 are side plan views of FIG. 5, but showing four different states.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean “at least one.”

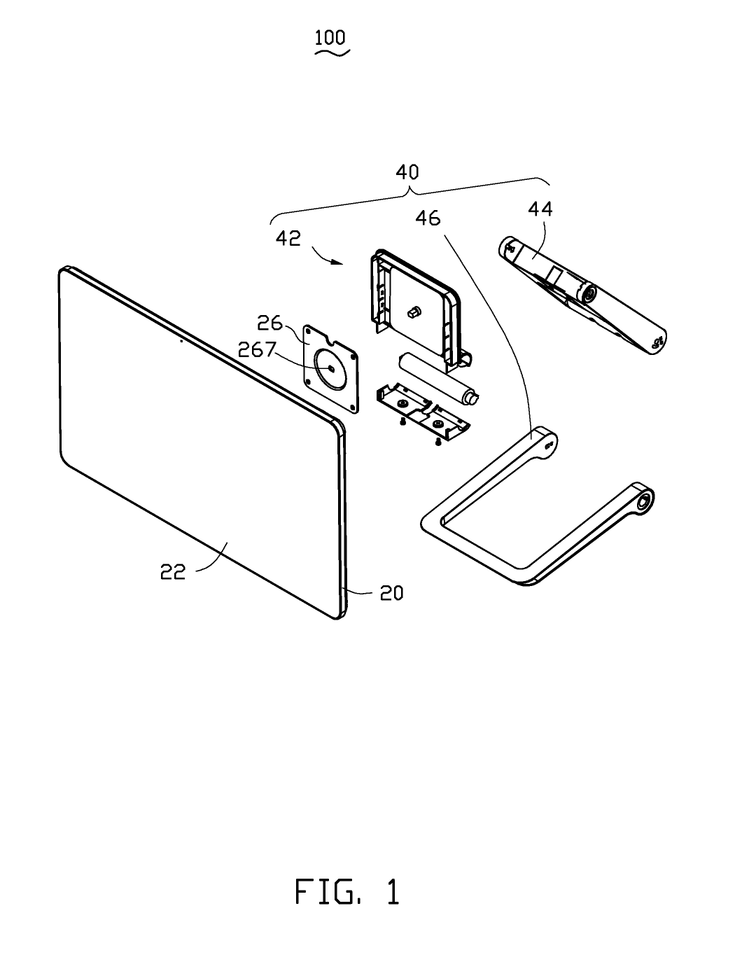

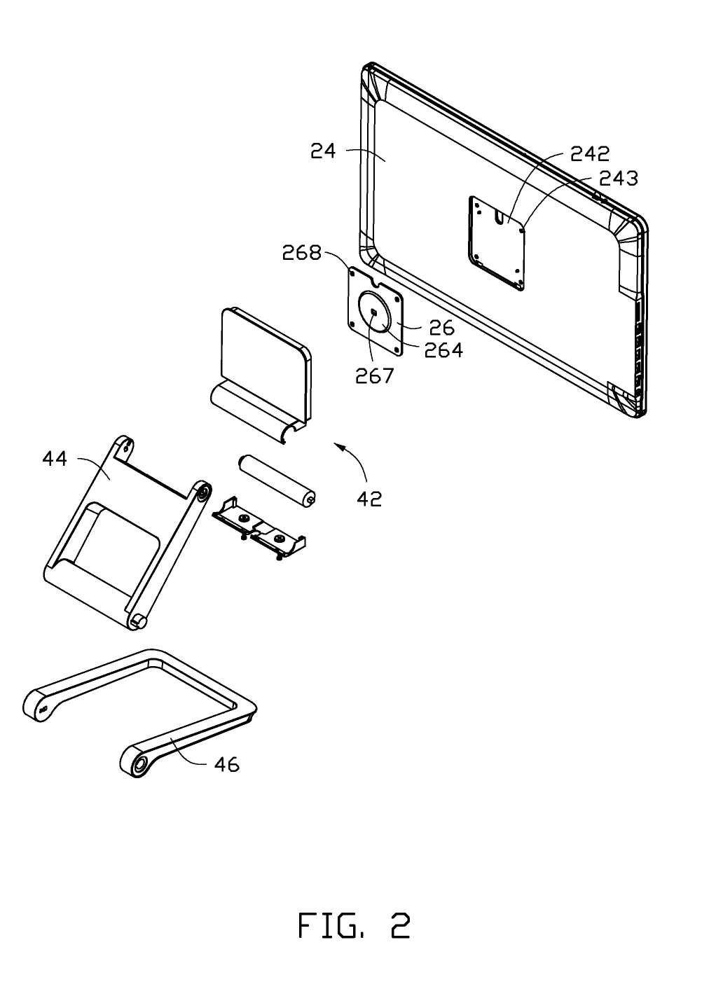

FIG. 1 and FIG. 2 show an embodiment of an electronic device 100 including a main body 20 and a supporting apparatus 40. The main body 20 includes a shell 24, a display screen 22 installed to a front side of the shell 24, and a positioning plate 26.

A rear side of the shell 24 opposite to the display screen 22 defines a depressed portion 242. A raised portion 264 protrudes rearward from a middle of the positioning plate 26. A middle of the raised portion 264 defines an installing hole 267. A bottom wall of the depressed portion 242 defines a plurality of screw holes 243. The positioning plate 26 defines a plurality of through holes 268 around the raised portion 264.

The supporting assembly 40 includes an installing assembly 42, a connecting assembly 44, and a support 46.

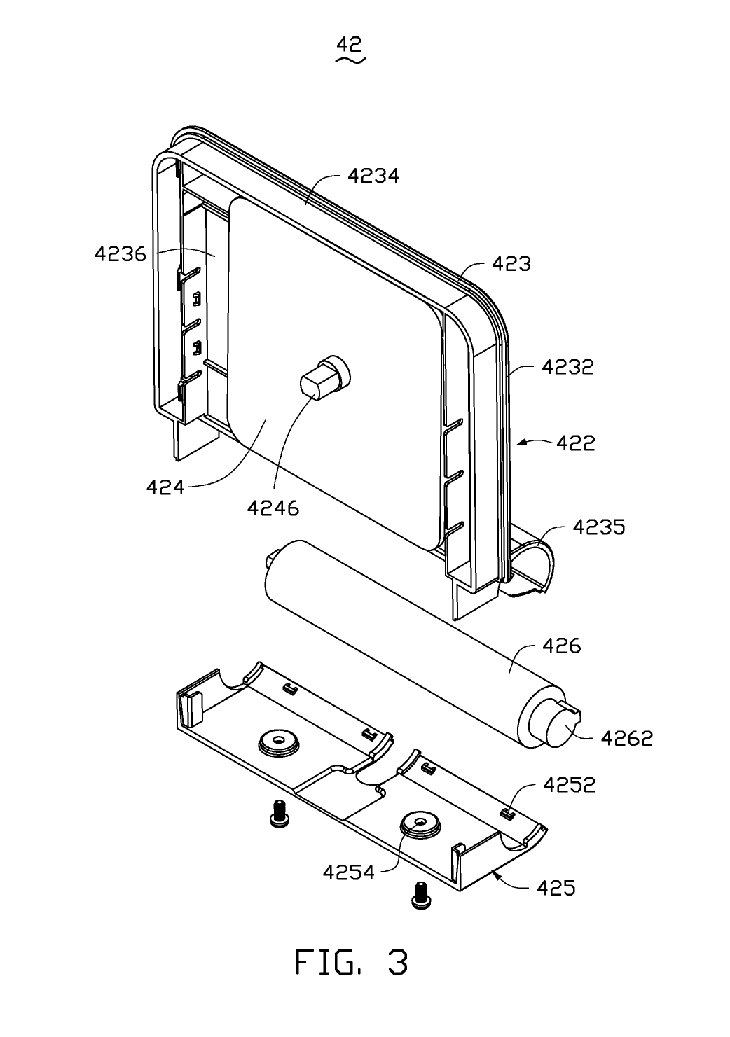

FIG. 3 shows the installing assembly 42 including a bracket 422, a mounting plate 424 mounted in the bracket 422, and a first hinge 426.

The bracket 422 includes a supporting member 423 and a positioning plate 425. The supporting member 423 includes a rectangular supporting plate 4232, a substantially U-shaped flange 4234 protruding forward from a top side and two opposite sides of the supporting plate 4232, and a sleeve 4235 protruding rearward from a bottom side of the supporting plate 4232. The supporting plate 4232 and the flange 4234 cooperatively bound an installation space 4236. The mounting plate 424 is received in the installation space 4236, and mounted to the supporting plate 4232. A plurality of hooks 4252 protrudes up from a rear side of the positioning plate 425, and can be latched to the sleeve 4235 of the supporting member 423. A middle of the positioning plate 425 defines two through holes 4254. A shaft 4246 is rotatably installed to a middle of the mounting plate 424. The first hinge 426 includes two connecting ends 4262 protruding out from two opposite ends of the first hinge 426.

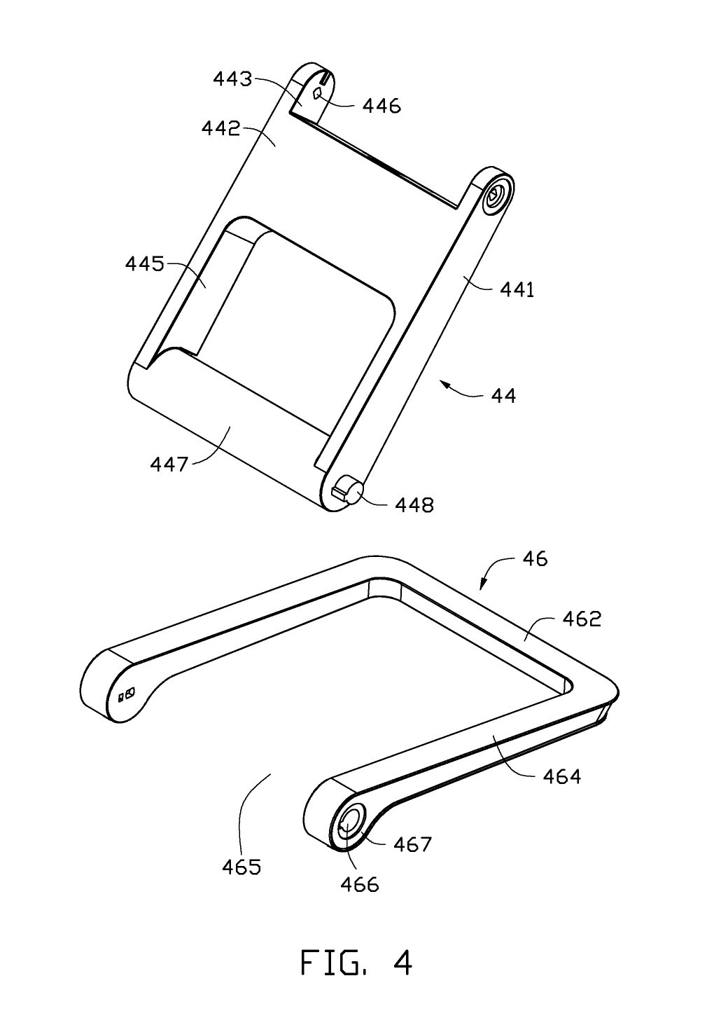

FIG. 4 shows the connecting assembly 44 and the support 46. The connecting assembly 44 includes a substantially H-shaped connecting member 441 and a second hinge 447. The connecting member 441 includes a rectangular connecting plate 442, two first connecting bars 443 perpendicularly protruding out from two opposite ends of a side of the connecting plate 442, and two second connecting bars 445 perpendicularly protruding out from two opposite ends of an opposite side of the connecting plate 442. Two distal ends of the first connecting bars 443 define two opposite installing holes 446. The second hinge 447 is installed between two distal ends of the second connecting bars 445. The second hinge 447 includes two connecting ends 448 protruding out from two opposite ends of the second hinge 447. The connecting ends 448 extend through the second connecting bars 445.

The support 46 is U-shaped, and includes a connecting pole 462, and two extending poles 464 perpendicularly extending out from two opposite ends of the connecting pole 462. The connecting pole 462 and the extending poles 464 cooperatively bound a receiving space 465. Two substantially cylindrical connecting portions 467 protrude down from two distal ends of the extending poles 464 opposite to the connecting pole 462. The connecting portions 467 define two opposite connecting holes 466.

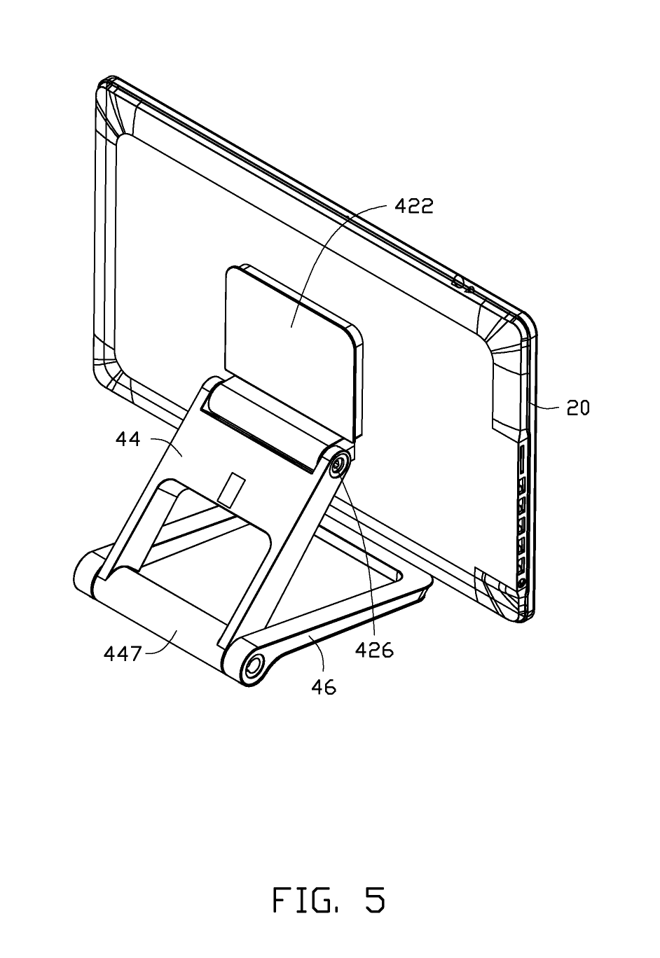

FIG. 5 shows in assembly of the electronic device 100. The first hinge 426 is received in the sleeve 4235, and the hooks 4252 of the positioning plate 425 are latched to the sleeve 4235. Two screws extend through the through holes 4254 of the positioning plate 425, to be mounted to the bottom of the bracket 422. The first hinge 426 is placed between the first connecting bars 443 of the connecting member 441, and the connecting ends 4262 of the first hinge 426 are inserted into the installing holes 446 of the connecting member 44. Thereby, the bracket 422 is rotatably connected to the connecting assembly 44 through the first hinge 426. The second hinge 447 is placed between the connecting portions 467, and two connecting ends 448 of the second hinge 447 are installed in the connecting holes 466 of the support 46. Thereby, the connecting assembly 44 is rotatably connected to the support 46 through the second hinge 447, and an axis of the first hinge 426 is parallel to an axis of the second hinge 447. The positioning plate 26 is received in the depressed portion 242 of the shell 24, with the raised portion 264 opposite to the bottom wall of the opening 242. A plurality of screws extends through the through holes 268, to be screwed in the corresponding screw holes 243. The shaft 4246 of the installing assembly 42 is latched in the installing hole 267 of the positioning plate 26. The main body 20 is rotatably supported on the supporting apparatus 40.

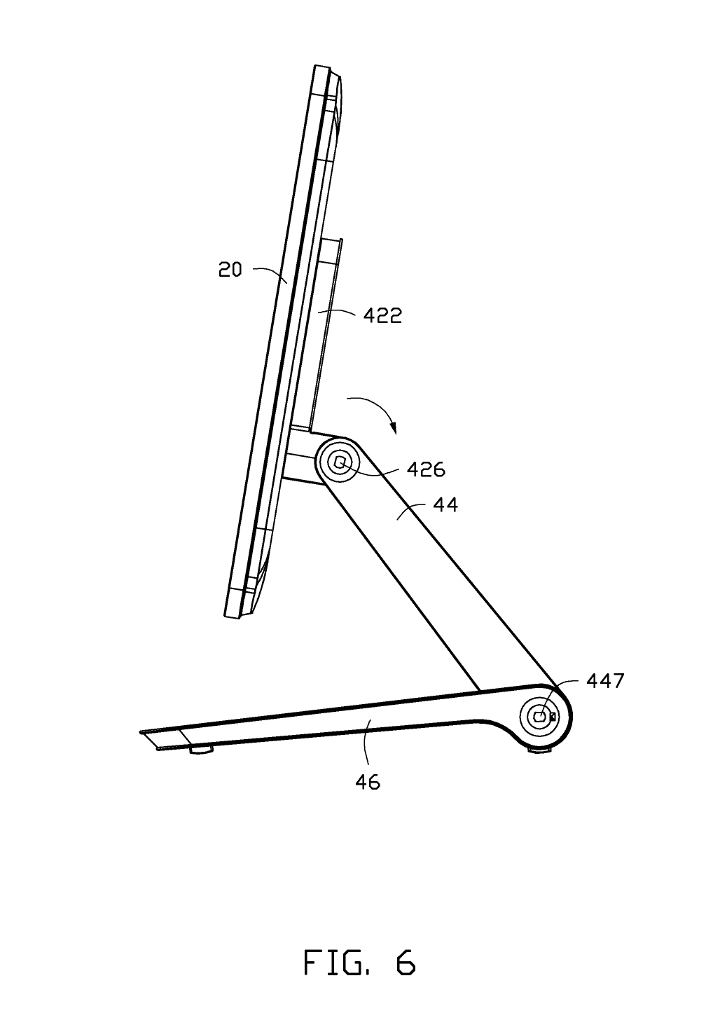

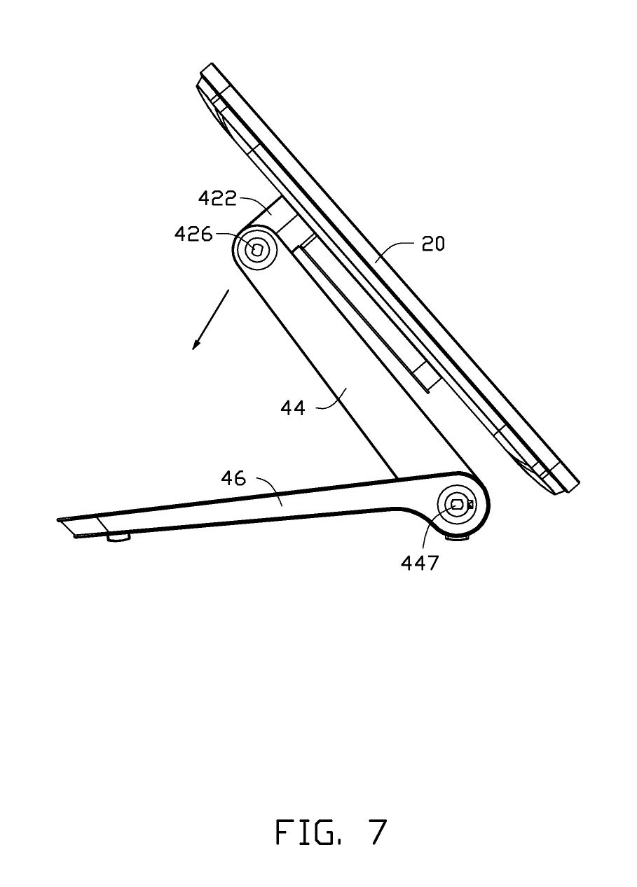

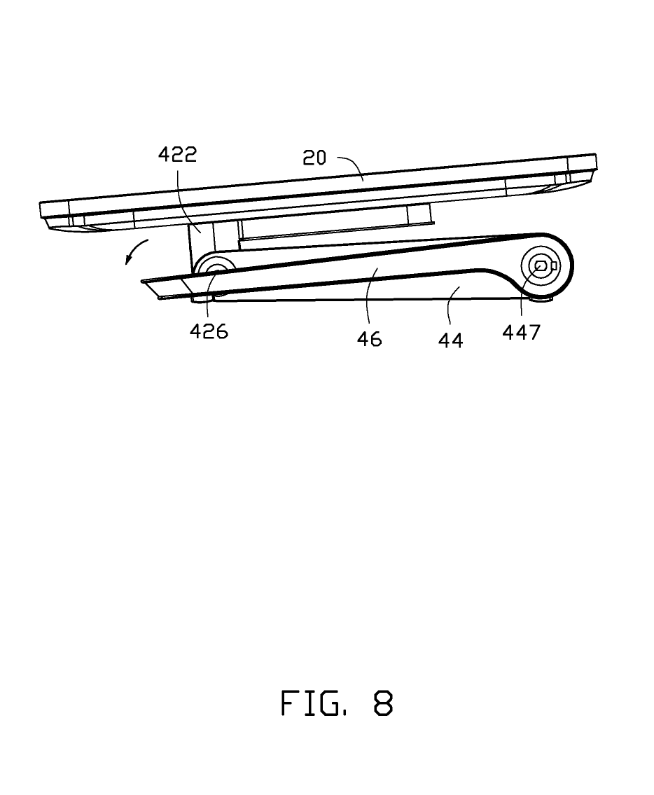

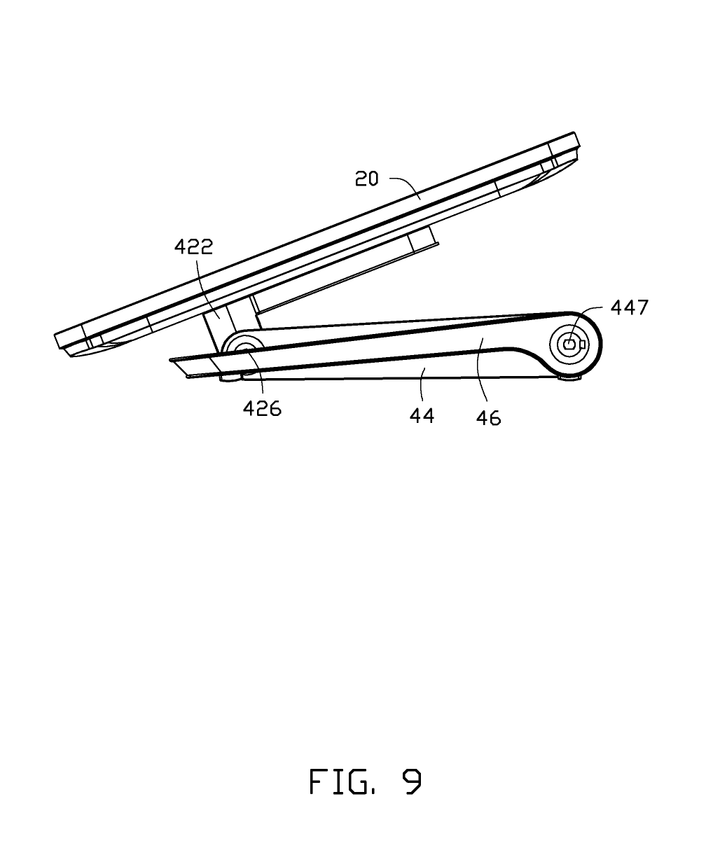

FIGS. 6-9 show that in use, the main body 20 can be rotated about the first hinge 426, to allow the display screen 22 to rotate forward or rearward. The connecting member 441 can be rotated about the second hinge 447 to be received in the receiving space 465 of the support 46, and the rear side of the main body 20 can contact the connecting member 441, which is convenient to hang the electronic device 100 on a wall (not shown).

It is to be understood, however, that even though numerous characteristics and advantages of the embodiment have been set forth in the foregoing description, together with details of the structure and function of the embodiment, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A supporting apparatus for an electronic device, the supporting apparatus comprising:
an installing assembly to be connected to the electronic device;
a support comprising a connecting pole and two opposite extending poles extending from two opposite ends of the connecting pole; and
a connecting assembly comprising a first end rotatably connected to the installing assembly, and a second end rotatably connected to the support;
wherein the connecting pole and the extending poles cooperatively bound a receiving space, the connecting assembly is operable of being rotated to be received in the receiving space.

2. The supporting apparatus of claim 1, wherein the installing assembly comprises a bracket and a mounting plate mounted in the bracket, a shaft is rotatably mounted to the mounting plate and is fixed to the electronic device.

3. The supporting apparatus of claim 2, wherein the bracket comprises a supporting plate and a flange protruding outward from a top side and two opposite sides of the supporting plate, the supporting plate and the flange cooperatively bound an installation space, the mounting plate is received in the installation space and is fixed to the supporting plate.

4. The supporting apparatus of claim 3, wherein the installing assembly further comprises a first hinge rotatably installed between the bracket and the connecting assembly.

5. The supporting apparatus of claim 4, wherein the bracket further comprises a sleeve protruding rearward from a bottom side of the supporting plate, the first hinge is received in the sleeve.

6. The supporting apparatus of claim 4, wherein the connecting assembly comprises an H-shaped connecting member and a second hinge, the connecting member comprises a connecting plate, two first connecting bars perpendicularly protruding out from two opposite ends of a side of the connecting plate, and two second connecting bars perpendicularly protruding out from two opposite ends of an opposite side of the connecting plate, the first hinge is installed between the first connecting bars, the second hinge is installed between the second connecting bars and connected between two distal ends of the extending poles of the support.

7. The supporting apparatus of claim 6, wherein an axis of the first hinge is parallel to an axis of the second hinge.

8. The supporting apparatus of claim 6, wherein two cylindrical connecting portions protrude down from the distal ends of the extending poles, the second hinge is rotatably connected between the connecting portions.

9. An electronic device, comprising:
a main body comprising a shell and a display screen installed in a front side of the shell;
an installing assembly connected to a rear side of the shell opposite to the display screen;
a support comprising a connecting pole and two opposite extending poles perpendicularly extending out from two opposite ends of the connecting pole; and
a connecting assembly comprising a first end rotatably connected to the installing assembly, and a second end rotatably connected to the support;
wherein the connecting pole and the extending poles cooperatively bound a receiving space, the connecting assembly is operable of being rotated to be received in the receiving space.

10. The electronic device of claim 9, wherein the shell defines a depressed portion in the rear side, a positioning plate is fixed in the depressed portion, the installing assembly comprises a bracket and a mounting plate mounted in the bracket, a shaft is rotatably mounted to the installing assembly, and is fixed to the positioning plate.

11. The electronic device of claim 10, wherein the bracket comprises a supporting plate and a flange protruding forward from a top side and two opposite sides of the supporting plate, the supporting plate and the flange cooperatively bound an installation space, the mounting plate is received in the installation space and is fixed to the supporting plate.

12. The electronic device of claim 11, wherein the installing assembly further comprises a first hinge rotatably installed between the bracket and the connecting assembly.

13. The electronic device of claim 12, wherein the bracket further comprises a sleeve protruding rearward from a bottom side of the supporting plate, the first hinge is received in the sleeve.

14. The electronic device of claim 12, wherein the connecting assembly comprises an H-shaped connecting member and a second hinge, the connecting member comprises a connecting plate, two first connecting bars perpendicularly protruding out from two opposite ends of a side of the connecting plate, and two second connecting bars perpendicularly protruding out from two opposite ends of an opposite side of the connecting plate, the first hinge is installed between the first connecting bars, the second hinge is installed between the second connecting bars and connected between two distal ends of the extending poles of the support.

15. The electronic device of claim 14, wherein an axis of the first hinge is parallel to an axis of the second hinge.

16. The electronic device of claim 14, wherein two cylindrical connecting portions protrude down from the distal ends of the extending poles, the second hinge is rotatably connected between the connecting portions.
